(19) United States
(12) Patent Application Publication
(10) Pub. No.: US 2026/0313801 A1
(43) Pub. Date: Oct. 8, 2026

(54) PCB STACK ELEMENT

(71) Applicant: HARTING AG, Biel (CH)

(72) Inventors: Gabriel SCHNEIDER, Wabern (CH); Thomas HESS, Meikirch (CH)

(21) Appl. No.: 19/484,824

(22) PCT Filed: Jun. 2, 2023
(86) PCT No.: PCT/IB2023/055717

§ 371 Date: Nov. 14, 2025

(51) Int. Cl. H05K 1/14; H05K 1/11; H05K 3/36

(52) U.S. Cl. CPC H05K 1/141; H05K 1/119; H05K 1/144; H05K 3/366; H05K 2201/042; H05K 2201/09118

(57) ABSTRACT

The invention relates to a PCB stack element (1) which is suitable for arranging electric and electronic components (4) on a circuit board (10). The PCB stack element (1) has a first circuit board (10) which extends in a first (X) and second (Y) direction, and the top side (11) and bottom side (12) of which are suitable for being populated with electric and electronic components (4). The PCB stack element (1) has at least two legs (13) which extend substantially perpendicularly to the first (X) and second (Y) direction of the circuit board (10) in a third direction (Z), wherein the legs (13) are suitable for supporting the circuit board (10) and for electrically contacting a second circuit board (2) such that the PCB stack element (1) is suitable for population on the second circuit board (2) and, with the first circuit board (10) of the PCB stack element (1) and with the second circuit board (2) populated with the PCB stack element (1), a PCB stack (100) is provided the first circuit board (10) and second circuit board (2) of which are arranged substantially parallel to one another and in particular one above the other.

### CROSS REFERENCE TO RELATED APPLICATION

The subject application is a US National Phase of PCT International Patent Application Serial No. PCT/IB2023/055717, Filed Jun. 2, 2023, the contents of which are incorporated herein by reference.

The invention relates to a PCB stack element provided for arranging electrical and electronic components on a printed circuit board. The invention in particular relates here to a PCB stack (printed circuit board stack) formed by means of the PCB stack element on the printed circuit board.

The invention additionally relates here in particular to a method for increasing the population density of a printed circuit board and/or a method for expanding the functionality of the printed circuit board, without significantly impairing its population density in the plane of the printed circuit board at the same time.

Such elements and methods are used for efficient space-saving operation of electrical and electronic devices.

### BACKGROUND OF THE INVENTION

Multilayer printed circuit boards enable complicated circuits to be implemented in a small structural space. The number of components which can be populated/soldered on a printed circuit board is limited by the surface area of the printed circuit board, however. This is because even with an increasing number of layers, the surface area that can be populated does not increase. In particular in applications in which the space is tight, complex designs using flexible printed circuit boards, soldered-on printed circuit boards, or additionally connected printed circuit boards have to be created to increase the area that can be populated, which results in complicated and costly solutions.

Populating printed circuit boards with electrical components in an automated manner is known from the prior art. In particular, this can take place by means of the widespread SMT technique (surface mounted technology).

One main problem in the automated populating of printed circuit boards is that these components often have individual connections. This makes both the printed circuit board layout and the flexibility of the populating with respect to the later selection of suitable components more difficult. In particular, the automation of the populating of the printed circuit board with alternative components, which would be very attractive in functional and price aspects, can be obstructed or even become impossible.

Due to their temperature sensitivity, many electrical components are not readily suitable for SMT soldering.

Furthermore, the lack of structural space on printed circuit boards is considered to be problematic for nearly all circuit designs, i.e. there is fundamentally the need to utilize the existing structural space as effectively as possible to enable the highest possible functionality with the least possible space consumption. In addition, the corresponding temperature development thereof can become problematic in the operation of high-performance electronic components, such as microprocessors, which makes it necessary to use heatsinks and/or fans, due to which the corresponding space requirement in turn increases further.

The prior art known from WO 2021/156793 A1 is directed to a component carrier for arranging electrical components on a printed circuit board, which is to be suitable for making the geometric arrangement of electrical components on a printed circuit board flexible, wherein especially component carriers made of MID-capable plastic are proposed, which can have a standardized footprint for connection to the printed circuit board and in particular can also be adapted in the LDS method by individually applied conductor tracks to the connections and the geometrical arrangement of the components.

The previously known component carrier extends, starting from a base component, which is arranged on the printed circuit board and is disadvantageously designed having a large area to provide a large number of electrical contacts with the printed circuit board, essentially vertically upward in relation to the printed circuit board. In particular with its base component, which is formed with a disadvantageously large area, the component carrier is not suitable for a space-saving expansion of the functionality of a printed circuit board and in particular for an efficient increase of the population density of a printed circuit board.

### SUMMARY OF THE INVENTION

The object of the invention is to provide a structural element suitable for many applications, which enables an increase of the population density of a printed circuit board and/or an expansion of the functionality of a printed circuit board, without at the same time impairing the population density of the components present on the printed circuit board, in particular in the plane of the printed circuit board.

It is in particular additionally the object of the invention here to provide a method suitable for the intended application of the structural element.

The invention relates in particular to a PCB stack element which comprises a first printed circuit board that extends in a first and second direction and the upper side and lower side of which are suitable for populating with electrical and electronic components.

The PCB stack element suitably comprises at least two legs, which extend in a third direction essentially perpendicular to the first and second direction of the printed circuit board, wherein the legs are designed suitably for supporting the first printed circuit board and for electrically contacting a second printed circuit board. The PCB stack element is therefore in particular advantageously suitable for its population on the second printed circuit board.

With the first printed circuit board of the PCB stack element and the second printed circuit board equipped with the PCB stack element, an advantageous PCB stack is provided, the first printed circuit board and second printed circuit board of which are arranged one over the other and in particular are arranged essentially parallel to one another here. Components can particularly advantageously be arranged here on the second printed circuit board below the first printed circuit board, and in particular provided components can also be arranged on an upper side and/or lower side of the first printed circuit board.

The components provided on the first printed circuit board therefore contribute to a desirable increase of the population density of electrical and in particular electronic components on the second printed circuit board, without the population density of the arrangement parallel to the second printed circuit board being disadvantageously impaired in this case.

The preceding PCB stack element can in particular be designed as a standard expansion element suitable for a variety of applications, which has contacts at the ends of its legs for contacting the second printed circuit board, which are suitable for soldering with predetermined connection points provided on the second printed circuit board and are designed accordingly.

The dimensions of the PCB stack element, and the number of its legs and the number of the contacts, as well as the height of the PCB stack element in the third direction and the thickness of the first printed circuit board are each designed here corresponding to the area that can be populated of the upper side of the first printed circuit board, wherein the area that can be populated of the printed circuit board can suitably be 9 mm² to 10,000 mm² and preferably 16 mm² to 625 mm², and particularly preferably 25 mm² to 400 mm².

A preceding standard expansion element which is suitable for many applications can be provided here by means of an advantageous first embodiment of the PCB stack element which is designed for an area that can be populated of the first printed circuit board of 9 mm² to 64 mm² and preferably of 16 mm² to 36 mm². The first embodiment of the PCB stack element can suitably have two legs each having, for example, a number of three contacts. The first embodiment of the PCB stack element can furthermore particularly preferably be designed for an area that can be populated of its circuit board of approximately 25 mm², and in particular can have a number of a total of six contacts here, which can be evenly distributed on the two legs, so that each leg has three contacts. It is clear that the number of the contacts is also dependent here on the final application for which the PCB stack element is intended, according to which more or fewer than three contacts can also be formed on one or both legs.

A preceding further standard expansion element which is suitable for many applications can additionally be provided by means of an advantageous second embodiment of the PCB stack element which is designed for an area that can be populated of the first printed circuit board of 64 mm² to 225 mm² and preferably of 64 mm² to 144 mm². The second embodiment of the PCB stack element can suitably have four legs each having a number of three to four contacts and advantageously three contacts here. The second embodiment of the PCB stack element can furthermore particularly preferably be designed for an area that can be populated of its printed circuit board of approximately 100 mm², and can have a number of a total of 12 contacts here, which can be evenly distributed on the four legs, so that each leg has three contacts. Of course, in the second embodiment of the PCB stack element, the number of the contacts is also dependent on the final application for which the PCB stack element is intended, according to which more or fewer than three or four contacts can also be formed on one or all legs.

A further standard expansion element which is suitable for many applications can additionally be provided by means of an advantageous third embodiment of the PCB stack element, which can be designed for an area that can be populated of the first printed circuit board of 225 mm² to 10,000 mm² and preferably of 225 mm² to 625 mm². The third embodiment of the PCB stack element can suitably have four legs each having a number of four to eight contacts here. The third embodiment of the PCB stack element can furthermore particularly preferably be designed for an area that can be populated of its printed circuit board of approximately 400 mm², and can have a number of a total of 24 contacts here, which can be evenly distributed on the four legs, so that each leg has six contacts. Of course, the statements made above with respect to the first and second embodiments likewise apply for the number of the contacts of the third embodiment, according to which the number of the contacts is also dependent on the final application for which the PCB stack element is intended, according to which fewer than four or more than eight contacts can also be formed on one or all legs.

From the preceding description of the essential features of the preferred embodiments of the PCB stack element, it can be seen that the above-described first, second, and third embodiments of the PCB stack element differ in particular in the area that can be populated thereof and the number of the legs and contacts thereof. Further differences between the first, second, and third embodiments, namely in the thickness of the first printed circuit boards, the thickness, length, and arrangement of the legs, which each advantageously correspond in particular with the area that can be populated, are described hereinafter in particular with reference to FIG. 3. A suitable selected contact form of the contacts provided at the ends of the legs for contacting the second printed circuit board is described hereinafter with reference to FIGS. 6A and 6B.

In particular also for a desirable stability and rigidity or flexibility, also with respect to temperature influence, a preceding PCB stack element can suitably be symmetrically formed, wherein particularly preferably the area that can be populated of the upper side of the printed circuit board can be formed square. In this context, reference is also made here to the following description with reference to FIG. 5. The preceding first, second, and third embodiments of the PCB stack element have here, with their preferred square area that can be populated of approximately 25 mm², 100 mm², and 400 mm², respectively, a width of approximately 5 mm, 10 mm, and 20 mm, respectively.

A preceding PCB stack element naturally also suitably has conductor tracks, which extend starting from the contacts provided on the legs for contacting the second printed circuit board to the area that can be populated of the upper side and/or lower side of the first printed circuit board.

An above-described PCB stack element can suitably be produced starting from a main body, which is provided using a suitable casting mold by means of thermoplastic injection molding or by means of additive manufacturing, particularly advantageously in a 3D-MID (molded interconnect device) method, wherein its conductor tracks can be manufactured in a simple manner by means of “LDS” (laser direct structuring) methods, and wherein the PCB stack element can be provided from a suitable plastic and in particular from LCP (liquid crystal copolyester), PPA (polyphthalamide), or PPS (polyphenylene sulfide). MID stands for “molded interconnect device” or “mechatronic integrated device”. These are injection molded circuit carriers made of plastic, to which metallic conductor tracks are applied. It is possible by means of 3D-MID to unify electronic and mechanical functions in a three-dimensional component and in particular also to provide a MEMS component (micro-electromechanical system).

Electrical or electronic components suitable for populating on the PCB stack element can in particular be microprocessors, LEDs, diodes, antennas, sensors, or, as already mentioned above, MEMS components or also a further PCB stack element.

For a required flexible geometric orientation of the components, in particular not only parallel to the first printed circuit board, but also perpendicular to the first printed circuit board, which can be of particularly great advantage in particular for antennas, acceleration sensors, and MEMS components, the PCB stack element can additionally have at least one carrier element, which extends essentially perpendicular to the first and second directions of the printed circuit board in the opposite direction to the third direction and provides a corresponding additional populating area for electrical or electronic components.

The legs of the PCB stack element can particularly advantageously each be arranged at an edge of the printed circuit board and can extend starting from the edge of the printed circuit board essentially in the third direction, because of which the PCB stack element has an advantageously stable structural form. The statements made above with respect to the legs also apply to the carrier element, which, like the legs, can likewise be arranged at an edge of the printed circuit board and can extend starting from the edge of the printed circuit board essentially in the opposite direction to the third direction.

As described above, a standardized expansion element, which can be suitable for many applications, can be provided by means of a PCB stack element in a preceding first, second, or third embodiment, which in particular differs in its dimensions of the respective area that can be populated of the first printed circuit board and the number of its contacts with the second printed circuit board.

For a particularly flexible use of the first, second, and third embodiments and for an extensive acquisition of a variety of different applications, a predetermined number of prefinished main bodies, in particular of the first, second, and third embodiments, can therefore be kept in stock in a component set according to one embodiment of the invention, so that they are advantageously available for rapid and flexible use and individual adaptation in accordance with their intended application and in accordance with a corresponding second printed circuit board.

The invention additionally relates here in particular to a PCB stack having an above-described second printed circuit board provided as the main board of the PCB stack and at least one preceding PCB stack element, which can also in particular be selected from a preceding component set, wherein the second printed circuit board is populated with the PCB stack element. A main board of the PCB stack is provided here by the second printed circuit board, which extends essentially in the first and second directions. A cover board of the PCB stack is provided by the first printed circuit board of the PCB stack element, which extends essentially parallel to the main board, wherein the printed circuit board layout of the main board having the PCB stack element and its intended population correspond.

The invention accordingly additionally relates in particular to a method for providing a preceding PCB stack for a predetermined application, wherein initially in a first step a suitable printed circuit board is selected as the main board of the PCB stack. In particular a printed circuit board can particularly advantageously be selected, the functions of which are additionally to be expanded by means of integration of further components, and which can also be arranged at least partially one over another on a preceding PCB stack element.

In a second step, at least one prefinished PCB stack element suitable for the predetermined application is also selected in particular from a preceding component set.

In a third step, a corresponding design of the printed circuit board layout of the main board and the PCB stack element suitable in each case for the preceding application as well as the number and arrangement of the above-described contacts of the PCB stack element are determined and defined, after which, in a fourth step, suitable conductor tracks are formed on the main board and the PCB stack element according to the printed circuit board layout of the main board and the PCB stack element defined in the third step.

Finally, in a fifth step, the main board and the PCB stack element are populated with their components provided in the third step, and subsequently thereto, in a sixth step, the main board is populated with the PCB stack element, after which a PCB stack according to an embodiment of the invention is provided, which has the main board and the PCB stack element arranged on the main board.

The method, as described above, is in particular also a method for increasing the population density of the main board and/or a method for expanding the functionality of the main board.

### BRIEF DESCRIPTION OF THE DRAWINGS

Exemplary embodiments of the invention are shown in the drawings and will be explained in more detail hereinafter. In the figures:

FIG. 1A shows a schematic perspective representation of a PCB stack element according to an embodiment of the invention;

FIG. 1B shows a schematic section through a PCB stack element according to an embodiment of the invention;

FIG. 2 shows a schematic perspective representation of a PCB stack element according to an embodiment of the invention from above and below;

FIG. 3 shows the PCB stack element from FIGS. 1A and 2 in each case in a shrunken representation together with a PCB stack element according to a further embodiment of the invention;

FIG. 4A shows a PCB stack provided by means of two PCB stack elements from FIG. 2 stacked one on top of the other;

FIG. 4B shows modifications of the PCB stack element from FIG. 2;

FIG. 5 shows schematic representations of the PCB stack elements from FIG. 3 from below together with further embodiments of a PCB stack element according to the invention;

FIG. 6A shows enlarged representations of a leg of the PCB stack element from FIG. 2 from below with differently formed selected contacts in each case;

FIG. 6B shows the detail A from FIG. 6A in an enlarged representation from a different perspective; and

FIG. 7 shows a schematic flow chart of method steps for producing a PCB stack according to an embodiment of the invention.

### DETAILED DESCRIPTION OF THE INVENTION

The figures contain schematic representations, some of which are simplified. Identical reference signs are partially used for equivalent, but possibly not identical elements. Various views of equivalent elements can be scaled differently. Not all reference signs are shown in all drawings.

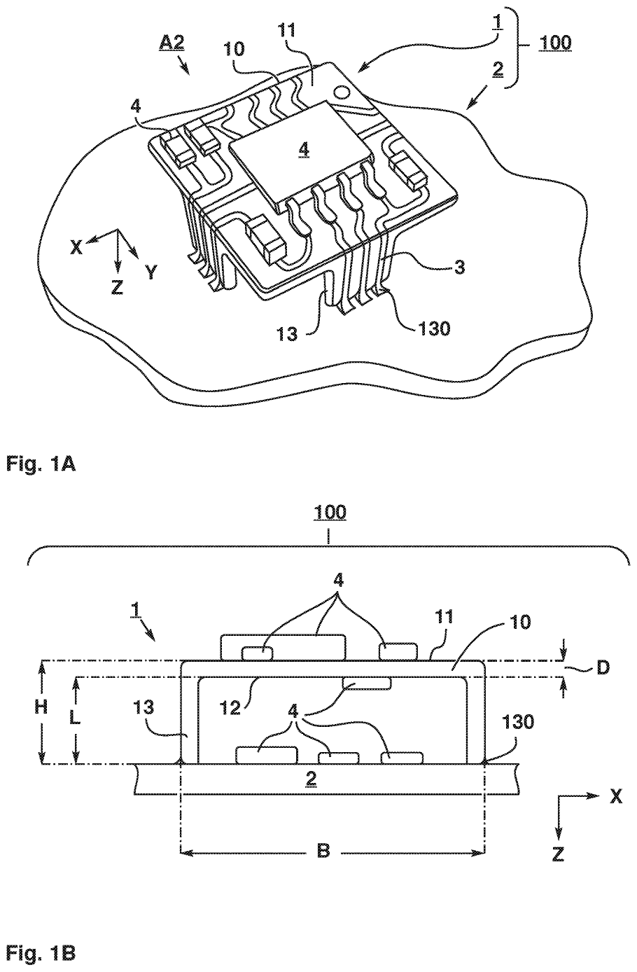

FIG. 1 shows a schematic perspective representation of a PCB stack element 1 according to an embodiment of the invention, which is arranged as intended on a printed circuit board 2 to provide a PCB stack 100 according to an embodiment of the invention, wherein the printed circuit board 2 forms the main board 2 of the PCB stack 100 and a printed circuit board 10 of the PCB stack element 1 forms the cover board 10 of the PCB stack 100.

The printed circuit board 10 of the PCB stack element extends in a first direction X and a second direction Y parallel to the printed circuit board 2. Four legs 13 extend perpendicular to the plane of the printed circuit board 10 in a third direction Z at the edge of the square printed circuit board 10. Three contacts 130, which are soldered with suitable contact points on the printed circuit board 2, are provided at the ends of each of the legs 13.

From the contacts 130 of the legs 13, conductor tracks 3 extend on the upper side 11 of the printed circuit board 10 and are connected to further conductor tracks 3 provided there, of the upper side 11 populated with electrical and electronic components 4. The components 4 can in particular also be microprocessors, LEDs, diodes, antennas, sensors, or MEMS components (micro-electromechanical systems), or a further PCB stack element 1.

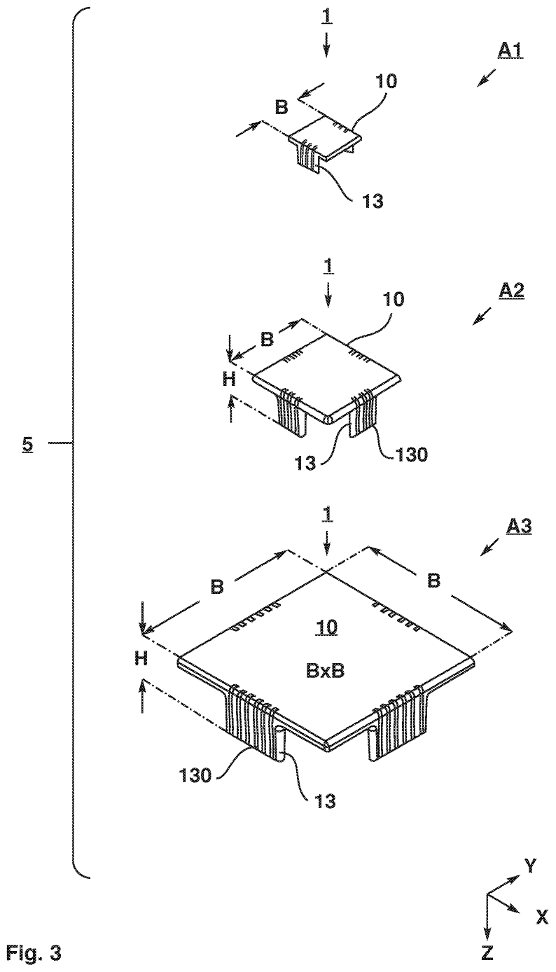

The PCB stack element 1 from FIG. 1A provides a PCB stack element 1 according to a second embodiment A2 of the invention, which has a square printed circuit board 10 and four legs 13 each having a number N1 of three contacts and therefore a total number N of 12 contacts. The PCB stack element 1 according to the second embodiment A2 of the invention will be described in more detail hereinafter in particular with reference to FIG. 3 in comparison to further embodiments A1 and A3 of the PCB stack element 1.

It is clear that the printed circuit board 2, like the printed circuit board 10 of the PCB stack element 1, is likewise provided with conductor tracks 3 and populated with components 4 for its intended application, which are not shown here for the sake of clarity and comprehensibility, wherein components 4 can advantageously also be arranged below the printed circuit board 10 and can be covered by the printed circuit board 10.

FIG. 1B shows for this purpose a schematic section through a PCB stack element 1 according to an embodiment of the invention along the first direction X and in the second direction Z. The PCB stack element 1 is likewise arranged on a printed circuit board 2 and, together with the printed circuit board 2, forms a PCB stack 100 according to an embodiment of the invention.

Three components 4 are arranged here by way of example on the upper side 11 of the printed circuit board 10, and the lower side 12 of the printed circuit board 10 is populated with one component 4 by way of example. Three components 4 are likewise arranged by way of example on the main board 2 below the printed circuit board 10, which in the PCB stack 100 forms a cover board 10 of the main board 2.

The printed circuit board 10 has a suitable thickness D for intended operation of the PCB stack element 1 having the components 4, so that the PCB stack element 1 has a desirable stability. The statement above applies in the same manner for the thickness D of the legs 13, which suitably essentially corresponds to the thickness D of the cover board 10, and for the height H of the PCB stack element 1, as well as the length L of the legs 13 corresponding to the height H. In particular the height H and length L are also selected suitably here for the thermally safe operation of the PCB stack element 1 and the components 4.

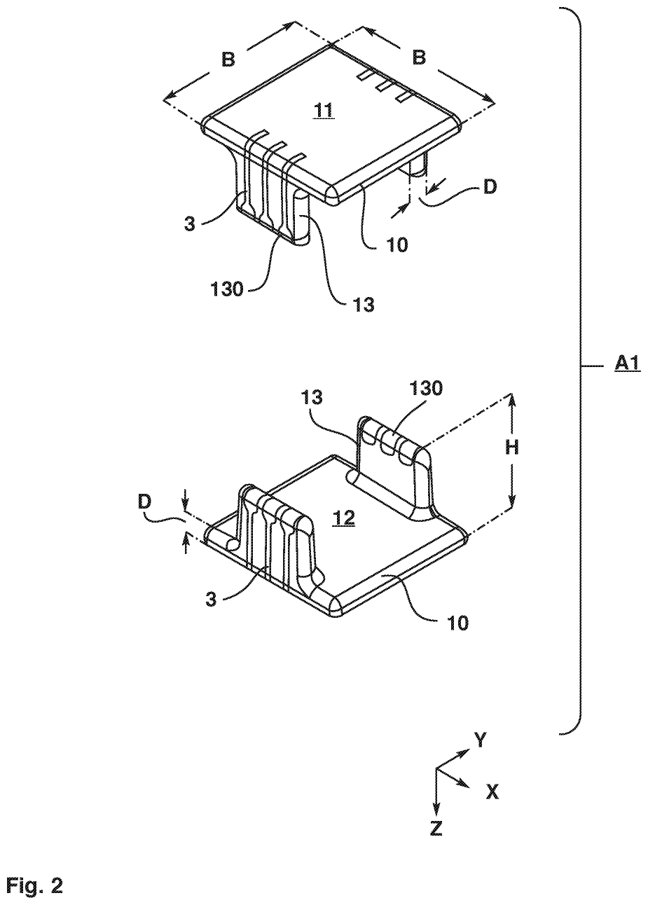

FIG. 2 shows a schematic perspective representation of a PCB stack element 1 according to a first embodiment A1 of the invention from above with a view of the upper side 11 of the printed circuit board 10 and from below with a view of its lower side 12. Like the embodiment A2 from FIG. 1A, the essentially square printed circuit board 10 having a width B and the corresponding dimensions B×B likewise has a correspondingly square upper side 11 that can be populated. In contrast to the second embodiment A2 of the PCB stack element 1 from FIG. 1A, the first embodiment A1 of the PCB stack element 1 only has two opposing legs 13 each having a number N1 of three contacts 130, wherein conductor tracks 3 starting from the three contacts 130 each extend on the outside of the legs 13 to the upper side 11 of the printed circuit board 10. The first embodiment A1 accordingly has a total number N of six contacts 130.

If also the lower side 12 of the printed circuit board 10 is populated with components 4, correspondingly suitable conductor tracks 3 (not shown in the drawing) can be laid from the upper side 11 via the edge of the printed circuit board 10 to the lower side 12. This also applies for the above-described second embodiment A2 and the third embodiment A3 of the PCB stack element 1 according to the invention, which is described hereinafter with reference to FIG. 3 together with the first embodiment A1 and the second embodiment A2. It is clear that alternatively or additionally to this measure, conductor tracks 3 can also be provided from the lower side 12 to the opposing sides of the legs 13, which extend from the lower side 12 to the contacts 130.

The thickness D of the printed circuit board 10 and the legs 13 is, like the height H of the PCB stack element 1, likewise selected corresponding to the width B such that a desirable stable PCB stack element 1 is provided, which also enables thermally safe operation in particular of its components 4. This also applies for the width and central arrangement of the legs 13 at two opposing edges of the printed circuit board 10.

FIG. 3 shows in an overview the above-described first embodiment A1 of the PCB stack element 1 from FIG. 2 and the second embodiment A2 from FIG. 1A, each in a shrunken representation together with a PCB stack element 1 according to a third embodiment A3 of the invention, wherein the first A1, second A2, and third A3 embodiment in particular differ in their dimensions B×B of their area that can be populated of the upper side 11 of the respective printed circuit board 10.

The smallest first embodiment A1 of a PCB stack element 1 has, in contrast to the second A2 and third A3 embodiment, as described above with reference to FIG. 2, only two legs 13, which by way of example each have a number N1 of three contacts. It is clear that a modified PCB stack element 1 of the embodiment A1 as described at the outset, intended for a special application, can also have fewer or more contacts 130. The embodiment A1 has an advantageous square printed circuit board 10 having dimensions B×B of 9 mm² to 64 mm² and preferably 16 mm² to 36 mm² and advantageously approximately 25 mm², wherein the width B of the PCB stack element 1 is approximately 5 mm at a height of advantageously approximately 2.5 mm. The thickness D of the printed circuit board 10 and the legs 13 of the first embodiment A1 is suitably 0.6 mm or 0.5 mm here.

The second embodiment A2 of a PCB stack element 1 has, in contrast to the above-described first embodiment A1, four legs 13, which each have a number N1 of three contacts by way of example. As for all embodiments described with reference to FIG. 3, it is also true for the embodiment A2 that a modified PCB stack element 1 of the embodiment A2, intended for a special application, can also have more or fewer contacts 130. The embodiment A2 likewise has an advantageous square printed circuit board 10 having dimensions B×B of 64 mm² to 225 mm² and preferably of 64 mm² to 144 mm² and advantageously approximately 100 mm², according to which the width B of the square PCB stack element 1 is approximately 10 mm. The height H is suitably approximately 4 mm here, and the thickness D of the printed circuit board 10 of the second embodiment A2 is suitably 0.8 mm here, while the thickness of the legs 13 in the area of the contacts 130 is slightly less at 0.6 mm.

The third embodiment A3 of a PCB stack element 1 likewise has, like the above-described second embodiment A2, four legs 13, each of which has a number N1 of six contacts by way of example. The third embodiment accordingly has a total number of N=24 contacts 130. As for all embodiments described with reference to FIG. 3, it is also true for the embodiment A3 that a modified PCB stack element 1 of the third embodiment A3, intended for a special application, can also have fewer or more contacts 130. The third embodiment A3 likewise has an advantageous square printed circuit board 10 having dimensions B×B of 225 mm² to 10,000 mm² and preferably of 225 mm² to 625 mm² and advantageously approximately 400 mm², according to which the width B of the square PCB stack element 1 is suitably approximately 20 mm. The height H is advantageously approximately 4 mm here. The thickness D of the printed circuit board 10 of the third embodiment A3 is suitably 1.1 mm here, while the thickness of the legs 13 in the area of the contacts 130 can be slightly less at 0.82 mm.

The printed circuit boards 10 of the above-described first A1, second A2, and third A3 embodiment of a PCB stack element 1 are each advantageously formed square, and the legs 13 are each arranged evenly distributed at the edges of the printed circuit board 10, according to which the PCB stack elements 1 have a preferably compact and stable structural form. It is clear that corresponding to selected applications, the printed circuit board 10 can also be formed rectangular, for example, and/or at least one of the legs 13 can also be arranged in each case spaced apart from the edge of the printed circuit board 10.

The preceding embodiments A1, A2, and A3, which essentially differ in their dimensions, are each intended for individual applications for providing a PCB stack 100 on a main board 2 and therefore can advantageously be kept in stock in a component set 5, wherein the number of the embodiments A1, A2, and A3 present in the component set 5 can suitably each be in a ratio to one another that corresponds to their current use.

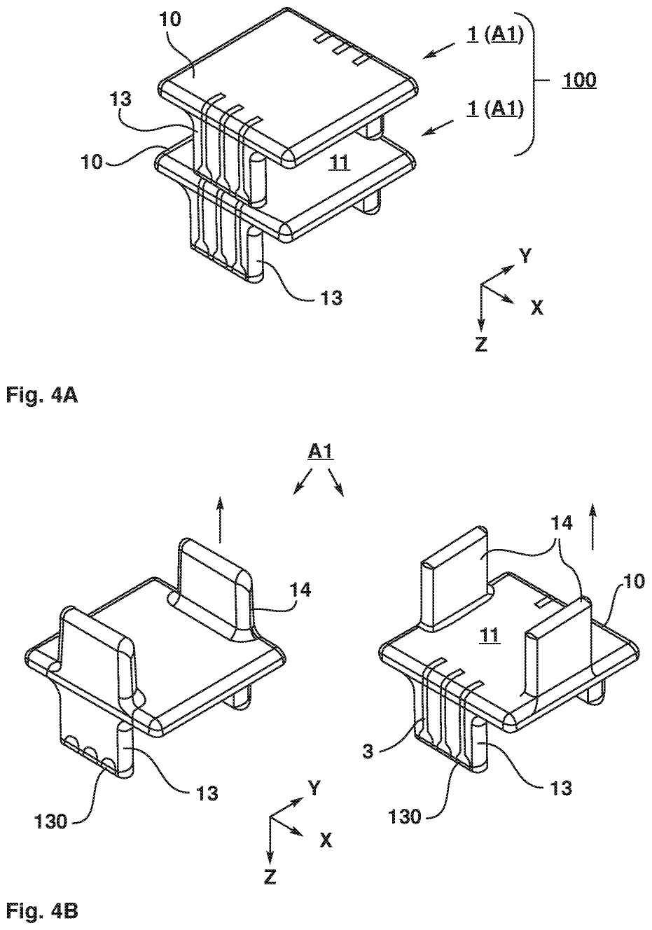

FIG. 4A shows a PCB stack 100, which is provided by means of two PCB stack elements 1 stacked one on top of the other, which can be advantageous for selected applications. Of course, the lower PCB stack element 1 is intended here to be arranged on a predetermined selected main board. The PCB stack 100 shown in the drawing is formed by way of example by means of two PCB stack elements 1 of the first embodiment A1. The legs 13 of the PCB stack elements 1 are arranged one on top of the other here by way of example each in the opposite direction to the third direction Z. It is clear that the upper PCB stack element 1 can also be arranged pivoted by 90° in relation to the lower PCB stack element 1 on the lower PCB stack element 1, and that in particular a PCB stack element 1 of the embodiment A1 can also be arranged centrally on a larger PCB stack element 1 of the embodiment A3.

FIG. 4B shows modifications of the PCB stack element 1 of the first embodiment A1 from FIG. 2, each of which has two carrier elements 14 which are arranged opposite at the edge of the printed circuit board 10 and each extend starting from the printed circuit board 10 in the opposite direction to the third direction Z. The carrier elements 14 are formed corresponding to the legs 13 and provide additional populating areas for electrical or electronic components 4, which can each extend perpendicular to the printed circuit board 10 in the first direction X and the third direction Z, or which can each extend in the second direction Y and the third direction Z.

The carrier elements 14 are advantageous in particular for a possibly required flexible geometric orientation of the components 4, in particular not only parallel to the printed circuit board 10, but also perpendicular to the printed circuit board 10, which is advantageous in particular for antennas, acceleration sensors, and MEMS components. It is clear that the embodiments A2 and A3 can likewise have such suitably formed and arranged carrier elements 14.

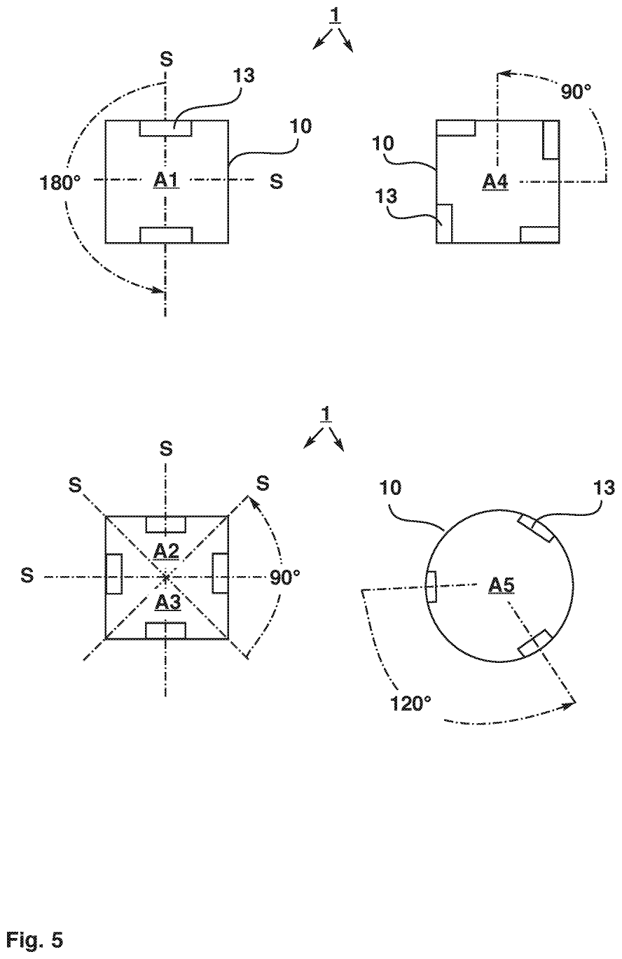

FIG. 5 shows schematic representations of the PCB stack elements 1 of the embodiments A1, A2, and A3 from FIG. 3 from below together with further embodiments A4 and A5 of a PCB stack element 1 according to the invention.

The further embodiments A4 and A5 shown in the drawing can have, like the above-described embodiments A1, A2, and A3, different dimensions, but are all scaled to one dimension for simpler comparison. Therefore, the embodiments A2 and A3, which otherwise do not differ, are also shown together in one depiction.

The embodiments A1 to A4 have an above-described advantageous square printed circuit board 10, and the embodiment A5 has a circular printed circuit board 10.

While the embodiments A2 and A3 have a comparatively high symmetry of four mirror planes S and a point symmetry of 90°, the embodiment A1 has two mirror planes S and a point symmetry of 180°, and the embodiments A4 and A5 do not have a mirror plane S and each only has a point symmetry of 90° or 120°, respectively.

However, the embodiments A4 and A5 likewise have, with their preceding point symmetries, a thermal stability and rigidity or flexibility in particular suitable for a PCB stack element 1 according to an embodiment of the invention, in particular also because the circular plane of the printed circuit board 10 is completely defined by the three legs 13 of the embodiment A5, and the arrangement of the four legs 13 of the embodiment A4, in comparison to the legs 13 of the embodiments of A2 and A3, is only shifted in the same manner counterclockwise toward the corners of the printed circuit board 10.

The above-described fourth A4 and fifth A5 embodiments are in each case exemplary modifications of the first A1, second A2, and third A3 embodiment, each of which can be designed corresponding to selected applications, wherein reference is made here to the statements above with reference to FIG. 3 with respect to possible further modifications not shown in FIG. 5.

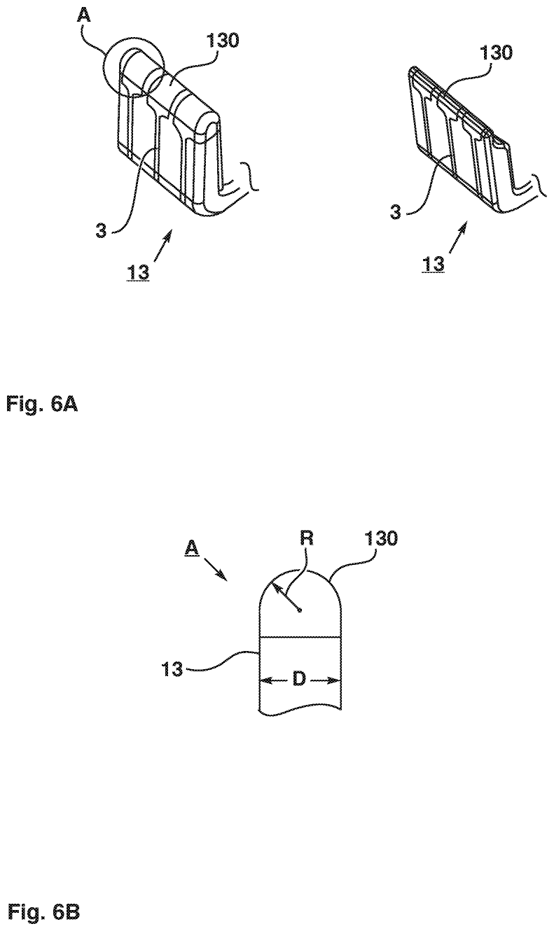

FIG. 6A shows enlarged representations of a leg 13 of the PCB stack element 1 from FIG. 2 from below having differently formed selected contacts 130 in each case, and FIG. 6B shows the detail A from FIG. 6A in an enlarged representation and from a different perspective.

The rounded contact form of the contacts 130 shown on the left side in the drawing advantageously extends over both sides of the leg 13 and corresponds to the advantageous contact form of the embodiment A1 from FIG. 2. With advantageously variable contact size, metallization of the lateral surfaces and checking of the soldered assembly are possible.

The rounded semicircular contact form of the contacts 130 at the end of the leg 13 suitably has a radius R here which corresponds to half the thickness D of the leg 13, which is schematically shown in the enlarged representation of the detail A from FIG. 6B.

The contact form of the contacts 130 shown on the right in FIG. 6A likewise extends like the preceding advantageous rounded contact form over both sides of the end of the leg 13, likewise enables a visual check, and requires an advantageously small amount of space for solder pads corresponding to the contacts 130 on the main board 2.

However, this contact form, in contrast to the preceding preferred rounded contact form, has thin wall thicknesses at the end of the leg 13, by which a design suitable for injection molding in the production is made more difficult and there is a risk for damage during production and handling.

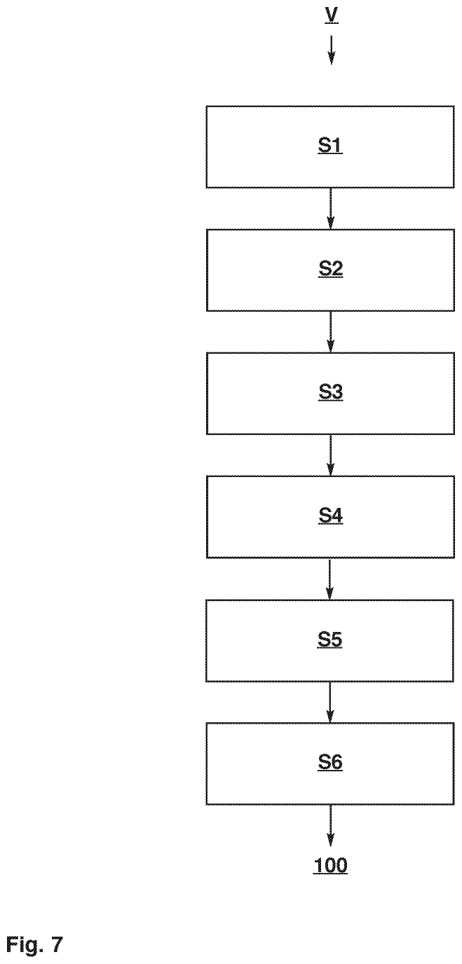

FIG. 7 shows a schematic flow chart of steps S1 to S6 of a method V for producing a PCB stack 100 for a predetermined application according to an embodiment of the invention.

Initially, in a first step S1, a suitable printed circuit board 2 is selected as the main board 2 of the PCB stack 100, wherein advantageously in particular a printed circuit board 2 can be selected, the functions of which are to be expanded by means of integration of further components 4, wherein the corresponding components 4 can be arranged at least partially one on top of another on a PCB stack element 1 according to an embodiment of the invention.

In a subsequent second step S2, at least one prefinished PCB stack element 1 suitable for the predetermined application is selected.

Subsequently thereto, in a third step S3, a corresponding design of the printed circuit board layout of the main board 2 and the PCB stack element 1 suitable in each case for the preceding application as well as the number and arrangement of the contacts 130 of the PCB stack element 1 are suitably determined and defined, after which, in a fourth step S4, according to the printed circuit board layout of the main board 2 and the PCB stack element 1 defined in step S3, suitable conductor tracks 3 on the main board 2 and the PCB stack element 1 as well as the contacts 130 are formed.

Finally, in a fifth step S5 of the method V, the main board 2 and the PCB stack element 1 are populated with their components 4 provided in the third step S3, and subsequently thereto, in a sixth step S6, the main board 2 is populated with the PCB stack element 1, after which a PCB stack 100 according to an embodiment of the invention is provided, which has the main board 2 and the PCB stack element 1 arranged on the main board 2.

### LIST OF REFERENCE SIGNS

1 PCB stack element
10 printed circuit board, cover printed circuit board
11 upper side
12 lower side
13 leg
130 contact
14 carrier element
100 PCB stack
2 printed circuit board, main board
3 conductor track
4 electrical or electronic component, microprocessor, LED, diode, antenna, sensor, MEMS component
5 component set
A detail
A1, A2, A3, A4, A5 embodiment
B width
B×B area, dimensions
D thickness
H height
L length
N, N1 number
S symmetry, mirror plane
S1, S2, S3, S4, S5, S6 step
R radius
V method
X, Y, Z direction

1. A PCB stack element for arranging electrical and electronic components on a printed circuit board, comprising the following features:
the PCB stack element has a first printed circuit board, which extends in a first and a second direction, and the upper side and lower side of which are configured for populating with electrical and electronic components; and
the PCB stack element has at least two legs, which extend essentially perpendicular to the first and the second direction of the printed circuit board in a third direction, wherein the legs are configured for supporting the printed circuit board and for electrically contacting a second printed circuit board, so that
the PCB stack element is configured for populating on the second printed circuit board, and with the first printed circuit board of the PCB stack element and the second printed circuit board populated with the PCB stack element, a PCB stack is provided, the first printed circuit board and second printed circuit board of which are arranged essentially parallel to one another and in particular one on top of the other.

2. The PCB stack element as claimed in claim 1, wherein contacts for contacting the second printed circuit board are provided at the ends of the legs, and
the dimensions of the PCB stack element, and the number of the legs and the number of the contacts, and
the height of the PCB stack element in the third direction and the thickness of the printed circuit board are each designed corresponding to the area configured to be populated of the upper side of the printed circuit board; and wherein the area configured to be populated of the printed circuit board is 9 mm² to 10,000 mm².

3. The PCB stack element as claimed in claim 2, wherein the PCB stack element is configured according to a preferred first embodiment for an area that is configured to be populated of its printed circuit board of 9 mm² to 64 mm² and preferably of 16 mm² to 36 mm², and has two legs each having a number of three contacts here; and wherein the PCB stack element is particularly preferably designed for an area that is configured to be populated of its printed circuit board of approximately 25 mm², and has a number of a total of six contacts.

4. The PCB stack element as claimed in claim 2, wherein the PCB stack element is configured according to a preferred second embodiment for an area that is configured to be populated of its printed circuit board of 64 mm² to 225 mm² and preferably of 64 mm² to 144 mm², and has four legs each having a number of three to four contacts; and wherein the PCB stack element is particularly preferably configured for an area that is configured to be populated of its printed circuit board of approximately 100 mm², and has a number of a total of 12 contacts.

5. The PCB stack element as claimed in claim 2, wherein the PCB stack element is configured according to a preferred third embodiment for an area that is configured to be populated of its printed circuit board of 225 mm² to 10,000 mm² and preferably of 225 mm² to 625 mm², and has four legs having a number of in each case four to eight contacts and wherein the PCB stack element is particularly preferably for an area that is configured to be populated of its printed circuit board of approximately 400 mm², and has a number of a total of 24 contacts.

6. The PCB stack element as claimed in claim 1, wherein the PCB stack element is designed symmetrically, and particularly preferably the area that is configured to be populated of the upper side of its printed circuit board is a square.

7. The PCB stack element as claimed in claim 2, wherein the PCB stack element has conductor tracks, which extend from the contacts to the area that is configured to be populated of the upper side and/or lower side of its printed circuit board.

8. The PCB stack element as claimed in claim 1, wherein the PCB stack element has at least one carrier element for electrical or electronic components, which extends from the printed circuit board essentially perpendicular to the first and the second direction of the printed circuit board in the opposite direction to the third direction.

9. The PCB stack element as claimed in claim 1, wherein the legs of the PCB stack element are each arranged at an edge of the printed circuit board and extend starting from the edge of the printed circuit board essentially in the third direction, and/or
the carrier element is arranged at an edge of the printed circuit board and extends starting from the edge of the printed circuit board essentially in the opposite direction to the third direction.

10. The PCB stack element as claimed in claim 1, wherein the PCB stack element is produced, starting from a main body provided using a casting mold by thermoplastic injection molding or by additive manufacturing, in a 3D-MID (molded interconnect device) method, and is manufactured with its conductor tracks by “LDS” (laser direct structuring) methods, wherein
the PCB stack element is provided in particular from LCP (liquid crystalline copolyester), PPA (polyphthalamide), or PPS (polyphenylene sulfide).

11. A component set for providing a PCB stack on a main board, having a plurality of PCB stack elements as claimed in claim 1, wherein
the PCB stack elements are prefinished starting from a main body provided using a casting mold by thermoplastic injection molding or by additive manufacturing, in a 3D-MID (molded interconnect device) method, and is manufactured with its conductor tracks by “LDS” (laser direct structuring) methods, wherein
the PCB stack element is provided in particular from LCP (liquid crystalline copolyester), PPA (polyphthalamide), or PPS (polyphenylene sulfide), and are available in accordance with their intended application for further individual application-related structuring and populating with components in accordance with a corresponding printed circuit board layout of the main board for their selection to provide the PCB stack, wherein the component set in particular has PCB stack elements according to a first, a second, and a third embodiment.

12. A PCB stack having a second printed circuit board provided as the main board of the PCB stack and at least one PCB stack element as claimed in claim 1, wherein
the second printed circuit board is populated with the PCB stack element; and
with the second printed circuit board, a main board of the PCB stack is provided, which extends essentially in the first and the second direction, and
with the first printed circuit board of the PCB stack element, a cover board of the PCB stack is provided, which extends spaced apart from the main board essentially parallel to the main board, wherein
the printed circuit board layout of the main board having the PCB stack element and its intended population correspond.

13. A method for providing a PCB stack as claimed in claim 12 for a predetermined application comprising the following steps:
selecting a printed circuit board as a main board of the PCB stack in a first step;
selecting at least one prefinished PCB stack element configured for the predetermined application in a second step;
determining and defining a respective corresponding design of the printed circuit board layout of the main board and the PCB stack element as well as the number and arrangement of the contacts of the PCB stack element, as well as its population with components in a third step;
forming conductor tracks and contacts according to the printed circuit board layout of the main board and the PCB stack element in a fourth step;
populating the main board and the PCB stack element with their components provided in the third step in a fifth step; and
populating the main board with the PCB stack element in a sixth step.

14. The method as claimed in claim 13, wherein
in the first step, a printed circuit board is selected, the functions of which are to be expanded by integration of further components, wherein the further components are arranged at least partially one on top of another on the PCB stack element.

15. The method as claimed in claim 13, wherein
for forming a PCB stack on the main board, a method for increasing the population density of the main board and/or a method for expanding the functionality of the main board is provided.

16. A PCB stack having a second printed circuit board provided as the main board of the PCB stack and at least one PCB stack element selected from the component set as claimed in claim 11, wherein
the second printed circuit board is populated with the PCB stack element; and
with the second printed circuit board, a main board of the PCB stack is provided, which extends essentially in the first and the second direction, and
with the first printed circuit board of the PCB stack element, a cover board of the PCB stack is provided, which extends spaced apart from the main board essentially parallel to the main board, wherein
the printed circuit board layout of the main board having the PCB stack element and its intended population correspond.

17. A method for providing a PCB stack as claimed in claim 16 for a predetermined application comprising the following steps:
selecting a printed circuit board as a main board of the PCB stack in a first step;
selecting at least one prefinished PCB stack element configured for the predetermined application in a second step;
determining and defining a respective corresponding design of the printed circuit board layout of the main board and the PCB stack element as well as the number and arrangement of the contacts of the PCB stack element, as well as its population with components in a third step;
forming conductor tracks and contacts according to the printed circuit board layout of the main board and the PCB stack element in a fourth step;
populating the main board and the PCB stack element with their components provided in the third step in a fifth step; and
populating the main board with the PCB stack element in a sixth step.

18. The method as claimed in claim 17, wherein
in the first step, a printed circuit board is selected, the functions of which are to be expanded by integration of further components, wherein the further components are arranged at least partially one on top of another on the PCB stack element.

19. The method as claimed in claim 14, wherein
for forming a PCB stack on the main board, a method for increasing the population density of the main board and/or a method for expanding the functionality of the main board is provided.
